(19) United States
(12) Patent Application Publication
(10) Pub. No.: US 2025/0293116 A1
(43) Pub. Date: Sep. 18, 2025

(54) SEMICONDUCTOR STORAGE DEVICE

(71) Applicant: Kioxia Corporation, Tokyo (JP)

(72) Inventor: Rei OKUBO, Yokohama Kanagawa (JP)

(73) Assignee: Kioxia Corporation, Tokyo (JP)

(21) Appl. No.: 18/978,223

(22) Filed: Dec. 12, 2024

(30) Foreign Application Priority Data
Mar. 15, 2024 (JP) 2024-040774

(51) Int. Cl. H01L 23/40; H01L 25/18; H10B 80/00

(52) U.S. Cl. CPC H01L 23/4006; H01L 25/18; H10B 80/00; H01L 2023/4062

(57) ABSTRACT

A semiconductor storage device according to one embodiment includes a housing, a board housed in the housing, a semiconductor memory provided on the board, and a heat dissipation structure provided in the housing.

### CROSS-REFERENCE TO RELATED APPLICATION

This application is based upon and claims the benefit of priority from Japanese Patent Application No. 2024-040774 filed on Mar. 15, 2024; the entire contents of which are incorporated herein by reference.

### FIELD

An embodiment of the present invention relates to a semiconductor storage device.

### BACKGROUND ART

A semiconductor storage device having a housing, a board housed in the housing, and a semiconductor memory provided on the board is known.

### BRIEF DESCRIPTION OF THE DRAWINGS

FIG. 1 is a perspective view showing a semiconductor storage device according to a first embodiment.

FIG. 2 is a perspective view showing a board unit according to the first embodiment.

FIG. 3 is an exploded perspective view showing a housing and a heat dissipation structure according to the first embodiment.

FIG. 4 is a perspective view showing a first part according to the first embodiment.

FIG. 5 is a perspective view showing a second part according to the first embodiment.

FIG. 6 is a cross-sectional view showing the semiconductor storage device along line F6-F6 shown in FIG. 1.

FIG. 7 is a cross-sectional view showing a first end part of the housing according to the first embodiment.

FIG. 8 is a cross-sectional view showing the housing and the heat dissipation structure according to the first embodiment.

FIG. 9 is a cross-sectional view showing the semiconductor storage device along line F9-F9 shown in FIG. 6.

FIG. 10 is a bottom view showing the semiconductor storage device according to the first embodiment.

FIG. 11 is a perspective view showing an assembly method of the semiconductor storage device according to the first embodiment.

FIG. 12 is a cross-sectional view showing an example of a usage environment of the semiconductor storage device according to the first embodiment.

FIG. 13 is a cross-sectional view for explaining a function of the heat dissipation structure according to the first embodiment.

FIG. 14 is a cross-sectional view showing a semiconductor storage device according to a second embodiment.

FIG. 15 is a cross-sectional view showing a semiconductor storage device according to a third embodiment.

FIG. 16 is a perspective view showing a semiconductor storage device according to a fourth embodiment.

### DETAILED DESCRIPTION

A semiconductor storage device according to one embodiment includes a housing, a board, a semiconductor memory, and a heat dissipation structure. The board is in the housing. The semiconductor memory is on the board. The heat dissipation structure is in the housing. The housing includes a first member and a second member. When a thickness direction of the board is defined as a first direction, the first member includes a first wall part, the first wall part includes a portion exposed to the outside of the housing, and the first wall part faces the board from a first side in the first direction. The second member includes a second wall part, the second wall part includes a portion exposed to the outside of the housing, the second wall part faces the board from a second side in the first direction, and the second side is on a side opposite to the first side. The heat dissipation structure includes a plurality of first fins, and the plurality of first fins protrude from the first wall part toward a side opposite to the board. The second member further includes a third wall part, the third wall part overlaps a part of the first member from the outside of the housing when viewed from a second direction, and the second direction is a direction in which the plurality of first fins are arranged.

Hereinafter, a semiconductor storage device according to an embodiment will be described with reference to the drawings. In the following description, components having the same or similar functions are denoted by the same reference signs. Also, duplicate description of the components may be omitted. In the present application, “parallel”, “orthogonal”, or “the same” may include a case of “substantially parallel”, “substantially orthogonal”, or “substantially the same”. “Connection” in the present application is not limited to a case of being mechanically connected, and may also include a case of being electrically connected. That is, “connection” is not limited to a case of being directly connected to an object, and may include a case of being connected to the object with another element interposed therebetween.

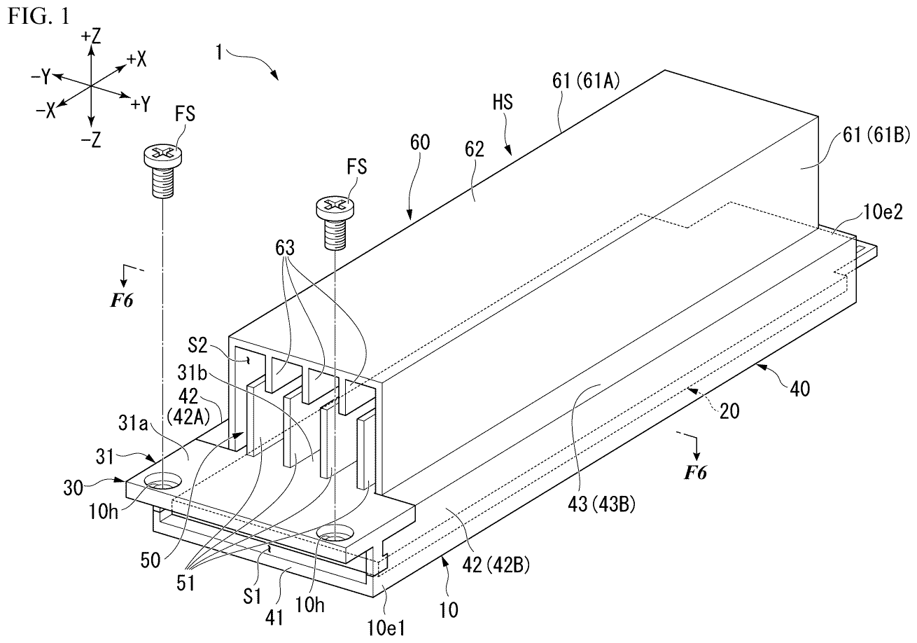

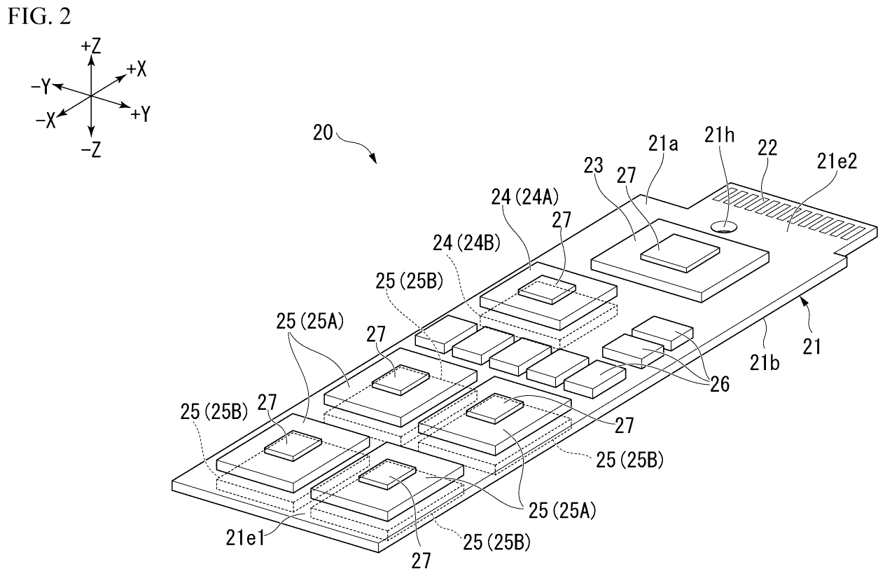

In the present application, a +X direction, a −X direction, a +Y direction, a −Y direction, a +Z direction, and a −Z direction are defined as follows. The +X direction, the −X direction, the +Y direction, and the −Y direction are directions parallel to a first surface 21a of a board 21 to be described later (see FIG. 2). The +X direction is a direction from a first end part 10e1 toward a second end part 10e2 of a housing 10 (see FIG. 1). The −X direction is a direction opposite to the +X direction. In a case in which the +X direction and the −X direction do not need to be distinguished from each other, they will be simply referred to as “X direction”. The +Y direction and the −Y direction are directions intersecting (for example, orthogonal to) the X direction. The +Y direction is a direction from one side wall (third wall 42A) toward the other side wall (third wall 42B) of the housing 10 to be described later (see FIG. 1). The −Y direction is a direction opposite to the +Y direction. In a case in which the +Y direction and the −Y direction do not need to be distinguished from each other, they will be simply referred to as “Y direction”. The +Z direction and the −Z direction are directions intersecting (for example, orthogonal to) the X direction and the Y direction. The +Z direction is a direction from a second wall 41 to a first wall 31 of the housing 10 to be described later (see FIG. 1). The −Z direction is a direction opposite to the +Z direction. In a case in which the +Z direction and the −Z direction do not need to be distinguished from each other, they will be simply referred to as “Z direction”. The Z direction is a thickness direction of the board 21. The Z direction is an example of a “first direction”. On the side in the +Z direction is an example of a “first side”. The side in the −Z direction is an example of a “second side”. The Y direction is an example of a “second direction”.

### First Embodiment

### <1. Overall Configuration of Semiconductor Storage Device>

A semiconductor storage device 1 according to a first embodiment will be described with reference to FIGS. 1 to 13. The semiconductor storage device 1 is a storage device such as, for example, a solid state drive (SSD). The semiconductor storage device 1 is connected to a host device and is used as a storage device for the host device. The host device may be a personal computer, a mobile device, a video recorder, an in-vehicle device, or the like, but is not limited to these examples.

FIG. 1 is a perspective view showing the semiconductor storage device 1. The semiconductor storage device 1 includes, for example, the housing 10, a board unit 20, and a heat dissipation structure HS. Here, the board unit 20 will be described first.

FIG. 2 is a perspective view showing the board unit 20. The board unit 20 is an assembly having on which parts including circuits are mounted. The board unit 20 includes, for example, the board 21, a connection connector 22, a controller 23, a plurality of dynamic random access memories (DRAMs) 24, a plurality of NAND flash memories 25 (hereinafter, referred to as “NANDs 25”), a plurality of capacitors 26, and a plurality of heat conductive members 27.

The board 21 is a plate member extending in the X direction and the Y direction. The board 21 is a printed circuit board. The board 21 includes an insulating base member and a wiring pattern provided on the insulating base member. The board 21 has the first surface 21a and a second surface 21b. The second surface 21b is positioned on a side opposite to the first surface 21a. The first surface 21a extends in the X direction and the Y direction. The first surface 21a is a surface facing in the +Z direction. The second surface 21b extends in the X direction and the Y direction. The second surface 21b is a surface facing in the −Z direction.

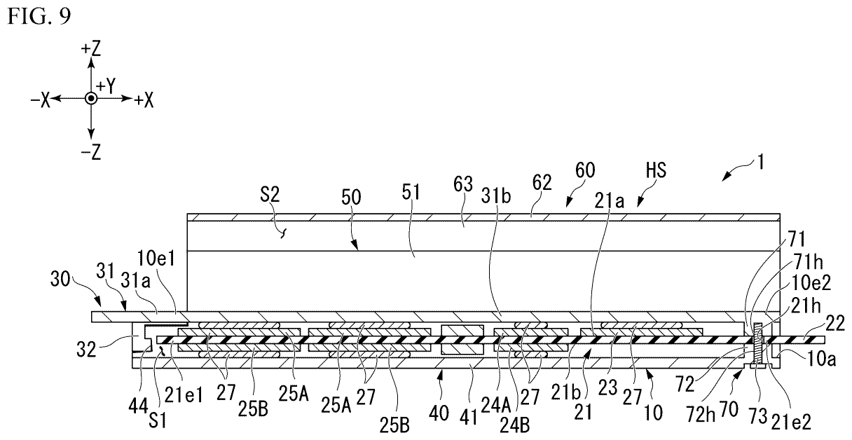

The board 21 has a first end part 21e1 and a second end part 21e2. The first end part 21e1 and the second end part 21e2 are end parts of the board 21 in a longitudinal direction (X direction). The first end part 21e1 is an end part of the board 21 on the side in the −X direction. The second end part 21e2 is an end part of the board 21 on the side in the +X direction. In the present embodiment, the second end part 21e2 of the board 21 has a through hole 21h. The through hole 21h penetrates the board 21 in the Z direction. A fastening member 73 (see FIG. 9) to be described later is inserted through the through hole 21h.

The connection connector 22 is a connection portion that can be connected to a connector of the host device. The connection connector 22 includes a plurality of metal terminals that can be connected to a connector of the host device. The connection connector 22 is provided, for example, on the second end part 21e2 of the board 21. The connection connector 22 is exposed to the outside of the housing 10 through an opening 10a of the housing 10 (see FIG. 9).

The controller 23 is a part that comprehensively controls the entirety of the semiconductor storage device 1. The controller 23 is a semiconductor package. Such a semiconductor package includes a system on a chip (SoC). In the system on a chip, for example, a host interface circuit for the host device, a control circuit configured to control the plurality of NANDs 25, and the like are integrated into one semiconductor chip. The controller 23 is provided, for example, on the first surface 21a of the board 21.

The DRAM 24 is a data buffer. In the data buffer, write target data received from the host device, read target data read from the NAND 25, or the like is to be temporarily stored. The plurality of DRAMs 24 include, for example, a DRAM 24A and a DRAM 24B. The DRAM 24A is provided on the first surface 21a of the board 21. The DRAM 24B is provided on the second surface 21b of the board 21. Note that, the number of the DRAMs 24 may be one. Also, the DRAM 24 may be provided inside the controller 23 as a part of the controller 23 instead of being provided as a separate part from the controller 23.

The NAND 25 is a semiconductor package that includes a nonvolatile semiconductor memory chip. The plurality of NANDs 25 include, for example, a plurality of NANDs 25A and a plurality of NANDs 25B. The plurality of NANDs 25A are provided on the first surface 21a of the board 21. The plurality of NANDs 25B are provided on the second surface 21b of the board 21. The NAND 25 is an example of a “semiconductor memory”. Note that, the “semiconductor memory as used in the present application is not limited to the NAND 25, but may be other types of semiconductor memory such as a NOR type memory, a magnetoresistive random access memory (MRAM), a resistive memory, or the like.

The capacitor 26 is one of the parts electrically connected to the board 21. The capacitor 26 assumes a power backup function for the purpose of data protection in the event of, for example, an unexpected power cutoff. In the present embodiment, the capacitor 26 supplies power to the controller 23, the plurality of DRAMs 24, and the plurality of NANDs 25 over a certain period of time when power supply from the host device is unexpectedly cut off.

The heat conductive member 27 is attached to each of the parts which are the controller 23, the DRAM 24, and the NAND 25 (hereinafter, these will be referred to as “heat generating parts”). The heat conductive member 27 is disposed between the heat generating part and an inner surface of the housing 10. The heat conductive member 27 is in contact with the heat generating part and the inner surface of the housing 10. The heat conductive member 27 transfers at least some of heat generated by the heat generating part to the housing 10.

### <2. Housing and Heat Dissipation Structure>

Next, returning to FIG. 1, the housing 10 and the heat dissipation structure HS will be described.

The housing 10 is a member that houses the board unit 20. The housing 10 has a housing space S1 in which the board unit 20 is housed. In the present application, the term “housing” means a member that defines a space (for example, the housing space S1) for housing electronic parts. Therefore, from one perspective, the heat dissipation structure HS to be described later can be said to be a heat dissipation structure that is present outside the housing 10.

The housing 10 has the first end part 10el and the second end part 10e2. The first end part 10e1 and the second end part 10e2 are end parts of the housing 10 in the longitudinal direction (X direction). The first end part 10e1 is an end part of the housing 10 on the side in the −X direction. The second end part 10e2 is an end part of the housing 10 on the side in the +X direction. In the present embodiment, the first end part 10e1 of the housing 10 has a pair of through holes 10h. The through holes 10h open in the Z direction. A fastening member FS (for example, a screw) is inserted through the through hole 10h. The fastening member FS fixes the semiconductor storage device 1 to a host device.

In the present embodiment, the heat dissipation structure HS is provided in the housing 10. The heat dissipation structure HS is formed, for example, integrally with the housing 10. However, the heat dissipation structure HS may be formed separately from the housing 10 and then attached to the housing 10 using a fixing portion (a fastening member such as a screw, welding, or an adhesive, or the like). In the present application, “the heat dissipation structure is provided in the housing” may include either a case in which the heat dissipation structure is formed integrally with the housing, or a case in which the heat dissipation structure is formed separately from the housing and then attached to the housing.

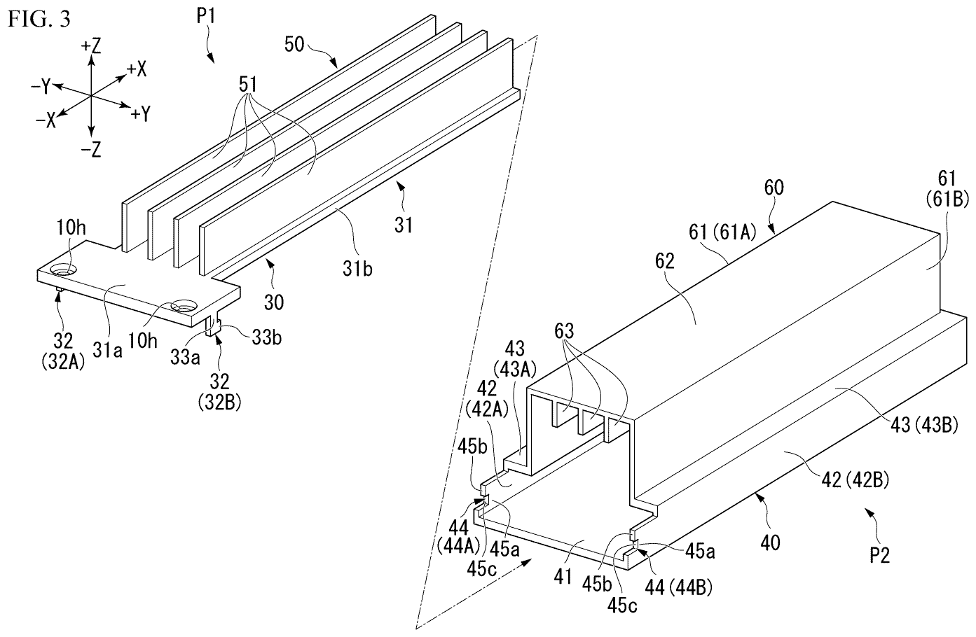

FIG. 3 is an exploded perspective showing the housing 10 and the heat dissipation structure HS. In the present embodiment, the housing 10 includes a first member 30 and a second member 40. The heat dissipation structure HS includes a first heat dissipation portion 50 and a second heat dissipation portion 60. The first heat dissipation portion 50 is formed integrally with the first member 30. The second heat dissipation portion 60 is formed integrally with the second member 40. Note that, alternatively, the first heat dissipation portion 50 may be formed separately from the first member 30 and then attached to the first member 30. The second heat dissipation portion 60 may be formed separately from the second member 40 and then attached to the second member 40. Hereinafter, for convenience of explanation, the first member 30 and the first heat dissipation portion 50 may be collectively referred to as a “first part P1”. Also, the second member 40 and the second heat dissipation portion 60 may be collectively referred to as a “second part P2”.

### <2.1 First Member>

First, the first member 30 will be described.

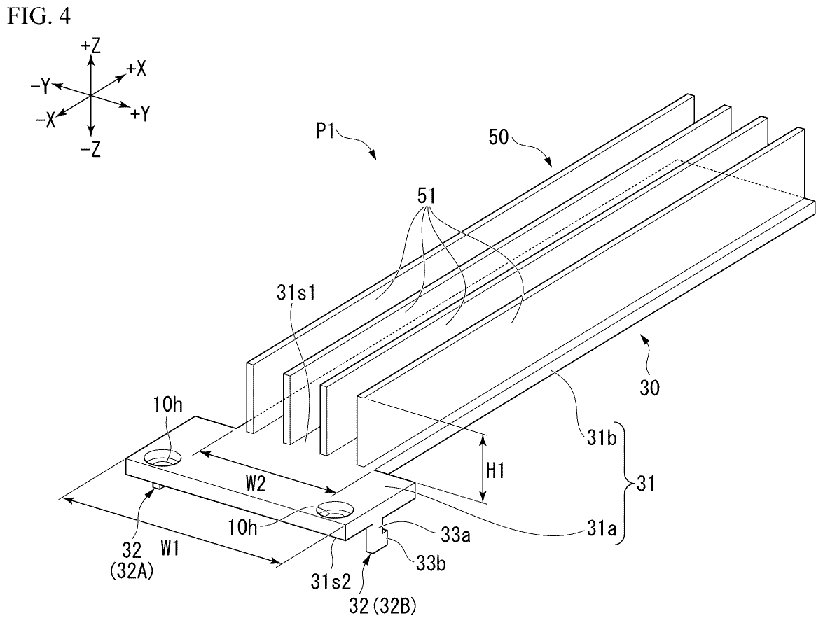

FIG. 4 is a perspective view showing the first part P1. The first member 30 is a member that forms a part of the housing 10. The first member 30 has, for example, the first wall 31 and a pair of engagement portions 32.

### <2.1.1 First Wall>

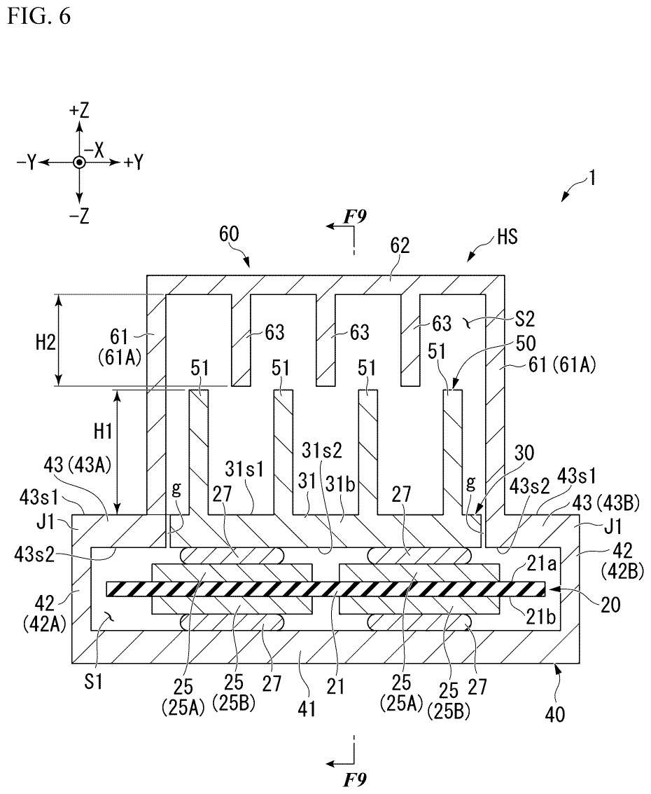

The first wall 31 is a plate-shaped wall extending in the X direction and the Y direction. The first wall 31 extends in the X direction. The first wall 31 defines a part of an end of the housing space S1 of the housing 10 on the side in the +Z direction (see FIG. 6). The first wall 31 is a portion that faces the housing space S1 from the side in the +Z direction. The first wall 31 is a portion that faces the board unit 20 from the side 5 in the +Z direction. The first wall 31 is an example of a “first wall part”. The first wall 31 has, for example, a first portion 31a and a second portion 31b.

The first portion 31a is positioned at the first end part 10el of the housing 10 (see FIG. 1). The first portion 31a is a region that does not overlap the heat dissipation structure HS when viewed from the Z direction. The first portion 31a is exposed to the outside of the housing 10 (for example, the outside of the semiconductor storage device 1). The first portion 31a is a portion that faces a part of the board unit 20 from the side in the +Z direction. The first portion 31a has the above-described through hole 10h. A width W1 of the first portion 31a in the Y direction has a size that spans between a pair of third walls 42A and 42B of the second member 40 to be described later.

The second portion 31b is integral with the first portion 31a. The second portion 31b extends in the +X direction from the first portion 31a. The second portion 31b is a region that overlaps the heat dissipation structure HS when viewed from the Z direction. The second portion 31b is a portion that faces a part of the board unit 20 from the side in the +Z direction. In the present embodiment, the width W2 of the second portion 31b in the Y direction is smaller than the width W1 of the first portion 31a in the Y direction.

Also, the first wall 31 has a first surface 31s1 and a second surface 31s2. The first surface 31s1 is a surface facing in the +Z direction. The second surface 31s2 is a surface facing in the −Z direction. The second surface 31s2 faces the housing space S1 of the housing 10.

The first wall 31 is thermally connected to each of the plurality of heat generating parts (for example, the controller 23, the DRAM 24A, and the plurality of NANDs 25A) mounted on the first surface 21a of the board 21 via the heat conductive member 27 (see FIGS. 6 and 9). At least some of heat generated by each of the plurality of heat generating parts (for example, the controller 23, the DRAM 24A, and the plurality of NANDs 25A) mounted on the first surface 21a of the board 21 is transferred to the first wall 31 via the heat conductive member 27.

### <2.1.2 Engagement Portion>

The pair of engagement portions 32 (engagement portions 32A and 32B) are provided on the first portion 31a of the first wall 31. The pair of engagement portions 32 are disposed separately at both end parts of the first portion 31a of the first wall 31 in the Y direction. The engagement portions 32 each protrude in the −Z direction from the first portion 31a of the first wall 31.

Each engagement portion 32 has, for example, a first portion 33a and a second portion 33b. The first portion 33a protrudes in the −Z direction from the first portion 31a of the first wall 31. The second portion 33b protrudes in the +X direction from an end part of the first portion 33a on the side in the −Z direction. A function of the engagement portion 32 will be described later. The engagement portion 32 is an example of a “second engagement portion”.

### <2.2 First Heat Dissipation Portion>

The first heat dissipation portion 50 is a heat dissipation portion that promotes heat dissipation from the first member 30. The first heat dissipation portion 50 promotes heat dissipation from the first member 30. Therefore, heat dissipation from the plurality of heat generating parts (for example, the controller 23, the DRAM 24A, and the plurality of NANDs 25A) mounted on the first surface 21a of the board 21 is promoted. In the present embodiment, the first member 30 and the first heat dissipation portion 50 are made of a metal (for example, aluminum or an aluminum alloy) and have high thermal conductivity.

The first heat dissipation portion 50 has a plurality of (for example, four) fins 51. The plurality of fins 51 are provided on the first wall 31 and protrude from the first wall 31 toward a side opposite to the housing space S1 (a side opposite to the board 21). The plurality of fins 51 are disposed to be aligned at regular intervals in the Y direction. Each of the fins 51 is a plate portion extending in the X direction and the Z direction. Each fin 51 extends in the X direction. For example, each fin 51 extends in the X direction to span a half or more of a length of the second portion 31b of the first wall 31 in the X direction. For example, each fin 51 extends in the X direction to span the entire length of the second portion 31b of the first wall 31 in the X direction. At least one fin 51 (for example, all of the fins 51) of the plurality of fins 51 overlaps the controller 23 and one or more NANDs 25 when viewed from the Z direction. The fin 51 is an example of a “first fin” and an example of a “protruding portion”.

In the present embodiment, a height H1 of each fin 51 in the Z direction is larger than the height H2 in the Z direction of a fin 63 of the second heat dissipation portion 60 to be described later (see FIG. 6). In the present embodiment, the number of the plurality of (for example, four) fins 51 is larger than the number of fins 63 (for example, three) of the second heat dissipation portion 60 to be described later (see FIG. 6).

### <2.3 Second Member>

Next, the second member 40 will be described.

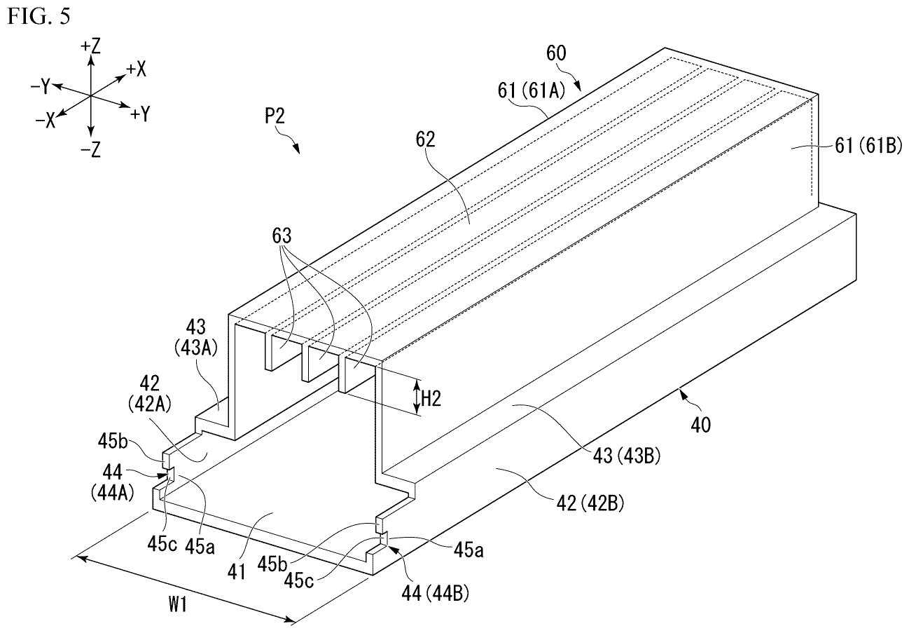

FIG. 5 is a perspective view showing the second part P2. The second member 40 is a member that forms another part of the housing 10. The second member 40 has, for example, the second wall 41, the pair of third walls 42, a pair of fourth walls 43, and a pair of engagement portions 44.

### <2.3.1 Second Wall>

The second wall 41 is a plate-shaped wall extending in the X direction and the Y direction. The second wall 41 extends in the X direction. A width of the second wall 41 in the Y direction is the same as the width W1 of the first portion 31a of the first wall 31 in the Y direction. A length of the second wall 41 in the X direction is the same as a length of the first wall 31 in the X direction. The second wall 41 is exposed to the outside of the housing 10 (for example, the outside of the semiconductor storage device 1). The second wall 41 defines an end of the housing space S1 of the housing 10 on the side in the −Z direction (see FIG. 6). The second wall 41 is a portion that faces the housing space S1 from the side in the −Z direction. The second wall 41 is a portion that faces the board unit 20 from the side in the −Z direction. The second wall 41 is an example of a “second wall part”.

The second wall 41 is thermally connected to each of the heat generating parts (for example, the DRAM 24B and the plurality of NANDs 25B) mounted on the second surface 21b of the board 21 via the heat conductive member 27 (see FIGS. 6 and 9). At least some of the heat generated by each of the heat generating parts (for example, the DRAM 24B and the plurality of NANDs 25B) mounted on the second surface 21b of the board 21 is transferred to the second wall 41 via the heat conductive members 27.

### <2.3.2 Third Wall>

Each of the pair of third walls 42 (third walls 42A and 42B) is a plate-shaped wall extending in the X direction and the Z direction. Each of the pair of third walls 42 stands upright from the second wall 41 in the +Z direction. For example, one third wall 42A stands upright in the +Z direction from an end part in the −Y direction of the second wall 41. The third wall 42A is a portion that faces the housing space S1 from the side in the −Y direction. The third wall 42A is a portion that faces the board unit 20 from the side in the −Y direction. The other third wall 42B stands upright in the +Z direction from an end part in the +Y direction of the second wall 41. The third wall 42B is a portion that faces the housing space S1 from the side in the +Y direction. The third wall 42B is a portion that faces the board unit 20 from the side in the +Y direction. Each of the pair of third walls 42 extends in the X direction.

FIG. 6 is a cross-sectional view showing the semiconductor storage device 1 along line F6-F6 shown in FIG. 1. Each of the pair of third walls 42 overlaps a part of the first member 30 from the outside of the housing 10 when viewed from the Y direction. For example, each of the pair of third walls 42 overlaps the first wall 31 of the first member 30 from the outside of the housing 10 when viewed from the Y direction. Each of the pair of third walls 42 corresponds to an example of a “third wall part”.

Note that, in the present application, a connection portion between two walls (for example, a connection portion J1 between the third wall 42 and the fourth wall 43) is a part of one wall (for example, the third wall 42) and also a part of another wall (the fourth wall 43). Therefore, in the present application, “the third wall 42 overlaps the first wall 31 when viewed from the Y direction” includes a case in which the connection portion J1 between the third wall 42 and the fourth wall 43 overlaps the first wall 31 when viewed from the Y direction.

### <2.3.3 Fourth Wall>

Each of the pair of fourth walls 43 (the fourth walls 43A and 43B) is a plate-shaped wall extending in the X direction and the Y direction. Each of the pair of fourth walls 43 extends from the third wall 42 in the Y direction. For example, one fourth wall 43A extends in the +Y direction from an end part in the +Z direction of the third wall 42A. The other fourth wall 43B extends in the −Y direction from an end part in the +Z direction of the third wall 42B. Each of the pair of fourth walls 43 defines a part of an end of the housing space S1 of the housing 10 on the side in the +Z direction (see FIG. 6). Each of the pair of fourth walls 43 is a portion that faces the housing space S1 from the side in the +Z direction. Each of the pair of fourth walls 43 is a portion that faces the board unit 20 from the side in the +Z direction. Each of the pair of fourth walls 43 extends in the X direction.

Each of the pair of fourth walls 43 overlaps a part of the first member 30 from the outside of the housing 10 when viewed from the Y direction. For example, each of the pair of fourth walls 43 overlaps the first wall 31 of the first member 30 from the outside of the housing 10 when viewed from the Y direction. Each of the pair of fourth walls 43 corresponds to another example of the “third wall part”.

The fourth wall 43 has a first surface 43s1 and a second surface 43s2. The first surface 43s1 is a surface facing on the side in the +Z direction. The first surface 43s1 is positioned, for example, on the same plane as the first surface 31s1 of the first wall 31 of the first member 30. The second surface 43s2 is a surface facing the side in the −Z direction. The second surface 43s2 faces the housing space S1 of the housing 10. The second surface 43s2 is positioned, for example, on the same plane as the second surface 31s2 of the first wall 31 of the first member 30. In the present embodiment, a cylindrical (for example, rectangular tubular) housing space S1 is defined by the first wall 31 of the first member 30, and the second wall 41, the third walls 42A and 42B, and the fourth walls 43A and 43B of the second member 40. The housing space S1 is open to the outside of the semiconductor storage device 1 in the +X direction and the −X direction.

### <2.3.4 Engagement Portion>

Returning to FIG. 5, the engagement portion 44 will be described. The pair of engagement portions 44 (engagement portions 44A and 44B) are provided at an end part of the third wall 42 on the side in the −X direction. One engagement portion 44A is provided at the end part of one third wall 42A on the side in the −X direction. The other engagement portion 44B is provided at the end part of the other third wall 42B on the side in the −X direction.

The engagement portion 44 has, for example, a first portion 45a and a second portion 45b. The second portion 45b is positioned on the side in the +Z direction of the first portion 45a. The second portion 45b protrudes further in the −X direction than the first portion 45a. Therefore, the engagement portion 44 has a recess 45c defined by a step between the first portion 45a and the second portion 45b. A function of the engagement portion 44 will be described later. The engagement portion 44 is an example of a “first engagement portion”.

### <2.4 Second Heat Dissipation Portion>

The second heat dissipation portion 60 is a heat dissipation portion that promotes heat dissipation from the second member 40. The second heat dissipation portion 60 promotes heat dissipation from the second member 40. Therefore, heat dissipation from the plurality of heat generating parts (for example, the DRAM 24B and the plurality of NANDs 25B) mounted on the second surface 21b of the board 21 is promoted. In the present embodiment, the second member 40 and the second heat dissipation portion 60 are made of a metal (for example, aluminum or an aluminum alloy) and have high thermal conductivity. The second heat dissipation portion 60 has, for example, a pair of upright portions 61, a ceiling portion 62, and the plurality of (for example, three) fins 63.

### (Upright Portion)

The pair of upright portions 61 (upright portions 61A and 61B) stand upright from the fourth wall 43 of the second member 40 to a side opposite to the housing space S1 (on the side in the +Z direction). One upright portion 61A stands upright in the +Z direction from an end part of one fourth wall 43A on the side in the +Y direction. The other upright portion 61B stands upright in the +Z direction from an end part of the other fourth wall 43B on the side in the −Y direction.

In the present embodiment, the upright portion 61 is a plate-shaped wall (upright wall) extending in the X direction and the Z direction. The upright portion 61 extends in the X direction. For example, the upright portion 61 extends in the X direction over a half or more of the length of the second portion 31b of the first wall 31 in the X direction. For example, the upright portion 61 extends in the X direction over the entire length of the second portion 31b of the first wall 31 in the X direction. At least a part of the upright portion 61 overlaps the plurality of fins 51 of the first heat dissipation portion 50 when viewed from the Y direction (see FIG. 6).

### (Ceiling Portion)

The ceiling portion 62 is a portion that covers the first heat dissipation portion 50 from the side in the +Z direction. The ceiling portion 62 is supported by the pair of upright portions 61. The ceiling portion 62 is disposed on a side opposite to the first wall 31 of the first member 30 with respect to the plurality of fins 51.

In the present embodiment, the ceiling portion 62 is a plate-shaped wall (ceiling wall) extending in the X direction and the Y direction. The ceiling portion 62 extends in the X direction. For example, the ceiling portion 62 extends in the X direction over a half or more of the length of the second portion 31b of the first wall 31 in the X direction. For example, the ceiling portion 62 extends in the X direction over the entire length of the second portion 31b of the first wall 31 in the X direction.

### (Plurality of Fins)

The plurality of fins 63 are provided on the ceiling portion 62. The plurality of fins 63 protrude from the ceiling portion 62 toward the side in the −Z direction. The plurality of fins 63 protrude from the ceiling portion 62 toward the first wall 31 of the first member 30. The plurality of fins 63 are disposed to be aligned at regular intervals in the Y direction. Each of the fins 63 is a plate portion extending in the X direction and the Z direction. Each fin 63 extends in the X direction. Each fin 63 extends in the X direction to span, for example, a half or more of the length of the second portion 31b of the first wall 31 in the X direction. Each fin 63 extends in the X direction to span, for example, the entire length of the second portion 31b of the first wall 31 in the X direction. The fin 63 is an example of a “second fin”.

In the present embodiment, at least one fin 63 included in the plurality of fins 63 of the second heat dissipation portion 60 is disposed in the Y direction to correspond to a position between two fins 51 included in the plurality of fins 51 of the first heat dissipation portion 50. Also, at least one fin 51 included in the plurality of fins 51 of the first heat dissipation portion 50 is disposed in the Y direction to correspond to a position between two fins 63 included in the plurality of fins 63 of the second heat dissipation portion 60. In the present embodiment, the fins 51 and the fins 63 are alternately disposed in the Y direction.

In the present embodiment, a cylindrical (for example, rectangular tubular) air flow path space S2 is defined by the first wall 31 of the first member 30, the pair of upright portions 61A and 61B of the second heat dissipation portion 60, and the ceiling portion 62 of the second heat dissipation portion 60 (see FIG. 6). The air flow path space S2 is open to the outside of the semiconductor storage device 1 in the +X direction and the −X direction. In the air flow path space S2, air can pass in the X direction. The plurality of fins 51 of the first heat dissipation portion 50 and the plurality of fins 63 of the second heat dissipation portion 60 are disposed inside the air flow path space S2.

### <3. Engagement Structure>

Next, an engagement structure between the first member 30 and the second member 40 will be described.

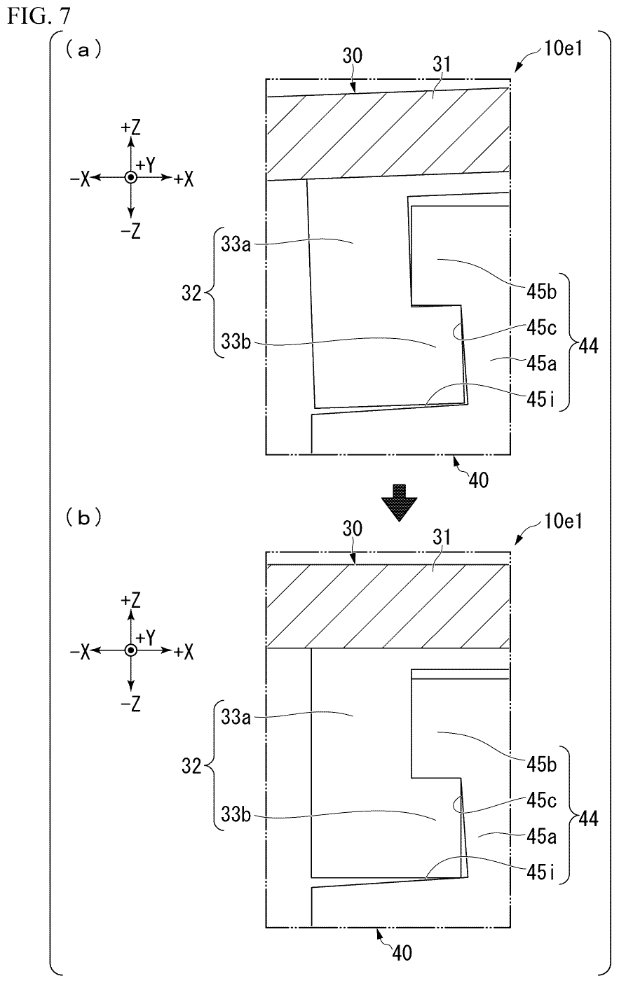

FIG. 7 is a cross-sectional view showing the first end part 10el of the housing 10. As described above, the engagement portion 32 of the first member 30 has the first portion 33a and the second portion 33b. The first portion 33a protrudes in the −Z direction from the first wall 31. The second portion 33b protrudes in the +X direction from the end part of the first portion 33a on the side in the −Z direction.

On the other hand, the engagement portion 44 of the second member 40 has the first portion 45a and the second portion 45b. The second portion 45b is positioned on the side in the +Z direction of the first portion 45a. The second portion 45b protrudes further in the −X direction than the first portion 45a. Therefore, the engagement portion 44 has the recess 45c defined by the step between the first portion 45a and the second portion 45b. The recess 45c is provided at a position corresponding to the second portion 33b of the engagement portion 32. When the second portion 33b of the engagement portion 32 is inserted into the recess 45c, a position of the first member 30 in the Z direction with respect to the second member 40 is restricted at the first end part 10el of the housing 10.

In the present embodiment, the engagement portion 44 has an inclined portion 45i. The inclined portion 45i is positioned on a side opposite to the second portion 45b with respect to the recess 45c. The inclined portion 45i is a portion facing the second portion 33b of the engagement portion 32 inserted into the recess 45c from a side opposite to the second portion 45b. The inclined portion 45i is inclined to become further away from the second portion 33b of the engagement portion 32 in the −X direction. The inclined portion 45i is inclined with respect to, for example, a horizontal plane.

When the inclined portion 45i is provided, the second portion 33b of the engagement portion 32 can be inserted into the recess 45c in a posture inclined with respect to the second portion 45b of the engagement portion 44 (see PART (a) of FIG. 7). Then, when the second portion 33b of the engagement portion 32 is made to be horizontal, a position of the first member 30 in the Z direction with respect to the second member 40 is restricted (see PART (b) of FIG. 7).

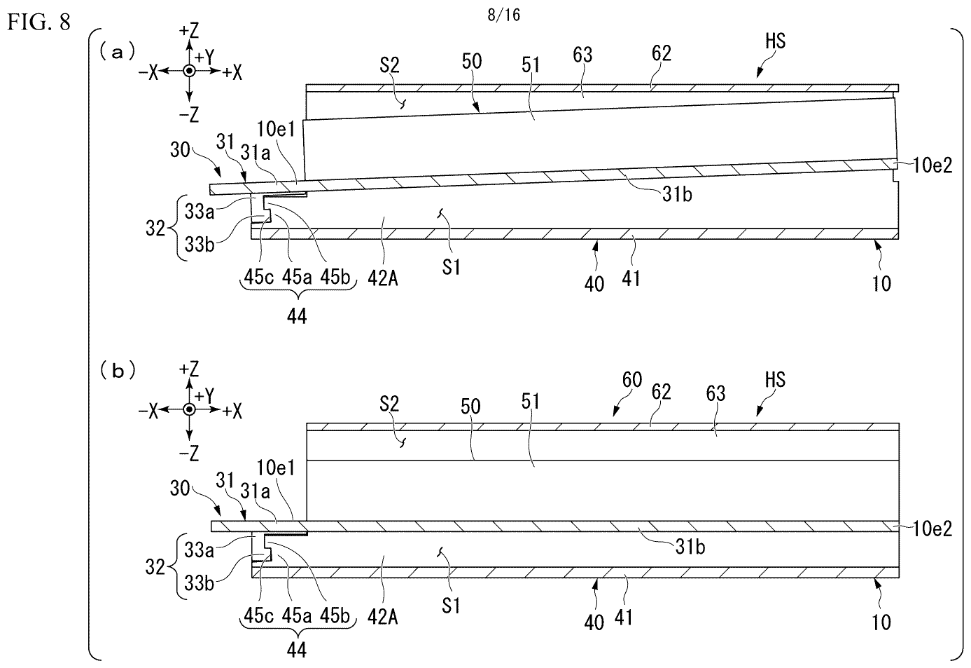

FIG. 8 is a cross-sectional view showing the housing 10 and the heat dissipation structure HS. In the present embodiment, the second portion 33b of the engagement portion 32 is inserted into the recess 45c in a posture in which the first member 30 is inclined with respect to the second member 40 (PART (a) of FIG. 8). Then, the first member 30 is made to be horizontal so that the first member 30 is parallel to the second member 40. Therefore, a position of the first member 30 in the Z direction with respect to the second member 40 is restricted at the first end part 10el of the housing 10 (see PART (b) of FIG. 8).

### <4. Fixing Structure>

Next, a fixing structure between the first member 30 and the second member 40 will be described.

FIG. 9 is a cross-sectional view showing the semiconductor storage device 1 along line F9-F9 shown in FIG. 6. The second end part 10e2 of the housing 10 has a fixing portion 70. The fixing portion 70 includes, for example, a first portion 71, a second portion 72, and the fastening member 73.

The first portion 71 is provided on the first wall 31 of the first member 30. For example, the first portion 71 is a protruding portion that protrudes in the −Z direction from the first wall 31 of the first member 30. The first portion 71 has a screw hole 71h that opens in the −Z direction. An inner circumferential surface of the screw hole 71h has a female thread. The screw hole 71h communicates with the through hole 21h of the board 21.

The second portion 72 is provided on the second wall 41 of the second member 40. For example, the second portion 72 is a protruding portion that protrudes in the +Z direction from the second wall 41 of the second member 40. The second portion 72 has a through hole 72h penetrating the second member 40 in the Z direction. The through hole 72h communicates with the through hole 21h of the board 21.

The fastening member 73 is a member that fastens the first member 30 and the second member 40 together. The fastening member 73 is, for example, a screw. The fastening member 73 is passed through the through hole 72h of the second portion 72 from the outside of the housing 10. The fastening member 73 that has been passed through the through hole 72h is passed through the through hole 21h of the board 21 and engages with the screw hole 71h of the first portion 71. When the fastening member 73 engages with the screw hole 71h, the first member 30 and the second member 40 are fixed together with the board 21 sandwiched between the first portion 71 and the second portion 72.

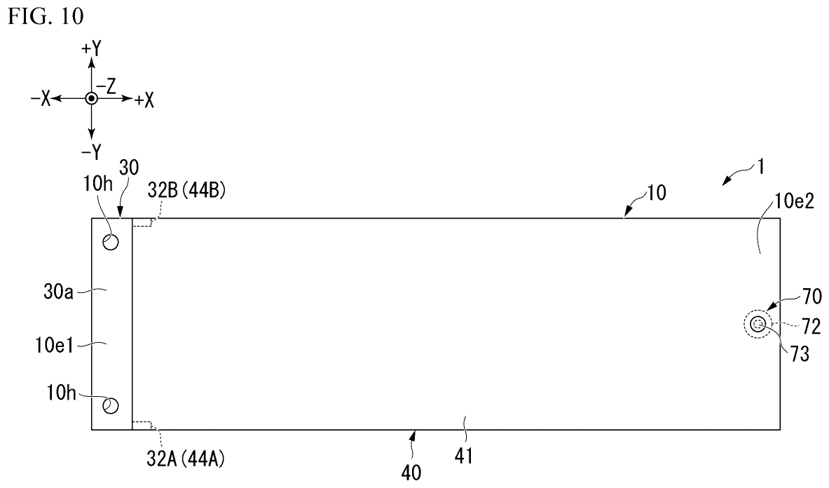

FIG. 10 is a bottom view showing the semiconductor storage device 1. In the present embodiment, the fixing portion 70 is provided at a center portion of the housing 10 in the Y direction at the second end part 10e2 of the housing 10. In the present embodiment, the fixing portion 70 is provided at only one location in the housing 10. The first member 30 and the second member 40 are fixed by one fastening member 73 with the engagement portions 32A and 32B hooked onto the engagement portions 44A and 44B.

### <5. Assembly Method>

Next, an assembly method of the semiconductor storage device 1 will be described.

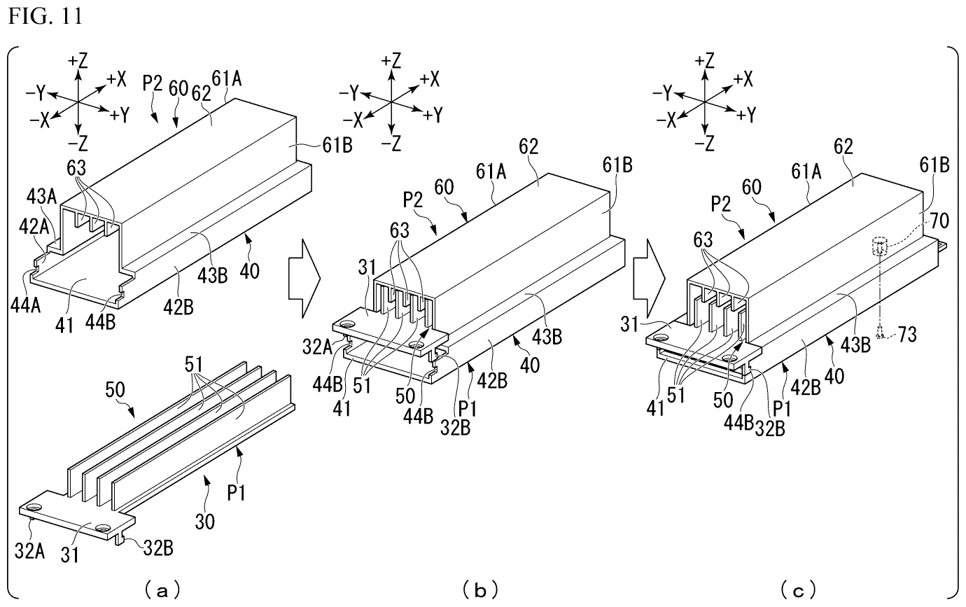

FIG. 11 is a perspective view for explaining an assembly method of the semiconductor storage device 1. First, the first part P1 in which the first member 30 and the first heat dissipation portion 50 are integrated, and the second part P2 in which the second member 40 and the second heat dissipation portion 60 are integrated are prepared (see PART (a) of FIG. 11). For example, the first part P1 is formed integrally by extrusion molding of the first member 30 and the first heat dissipation portion 50. For example, the second part P2 is formed integrally by extrusion molding of the second member 40 and the second heat dissipation portion 60.

Next, the board unit 20 is inserted into the second part P2. The board unit 20 is placed on the second wall 41 of the second member 40 via the heat conductive member 27. Also, a part of the board 21 is placed on the second portion 72 of the fixing portion 70 (see FIG. 9).

Next, the first part P1 is inserted inside the second part P2 such that the fins 51 of the first heat dissipation portion 50 are inserted between the plurality of fins 63 of the second heat dissipation portion 60 (see PART (b) of FIG. 11). For example, the first part P1 can be inserted into the inside of the second part P2 in the X direction by aligning left and right side portions of the first wall 31 with inner surfaces of the upright portions 61A and 61B of the second heat dissipation portion 60, and then being guided by the inner surfaces of the upright portions 61A and 61B.

Next, the engagement portions 32A and 32B of the first member 30 are engaged with the engagement portions 44A and 44B of the second member 40 in a posture in which the first part P1 is inclined in the Z direction with respect to the second part P2 (see PART (a) of FIG. 8). Next, the first part P1 is placed in a posture parallel to the second part P2 (see PART (b) in FIG. 8). Then, the first member 30 and the second member 40 are fixed together using the fastening member 73 (see PART (c) of FIG. 11). Therefore, the first part P1 and the second part P2 are integrated together. The board unit 20 is sandwiched between the first wall 31 of the first member 30 and the second wall 41 of the second member 40 via the heat conductive member 27. Therefore, assembly of the semiconductor storage device 1 is completed.

### <6. Function>

Next, a function of the heat dissipation structure HS will be described.

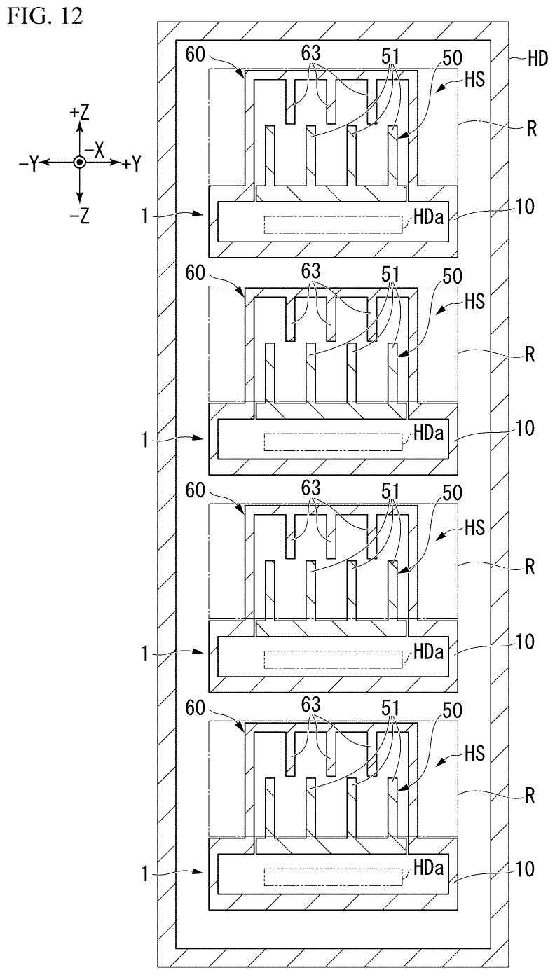

FIG. 12 is a cross-sectional view showing an example of a usage environment of the semiconductor storage device 1. FIG. 12 shows a usage environment in which the semiconductor storage device 1 is connected to a connector HDa of a host device HD. Note that, for convenience of explanation, illustration of the board unit 20 is omitted in FIG. 12.

As shown in FIG. 12, a plurality of semiconductor storage devices are disposed to be aligned, for example, in the Z direction. In the host device HD, a position in the Z direction of the connector HDa, to which the semiconductor storage device 1 is connected, is determined by standards or specifications. Also, in the host device HD, a region R in which the heat dissipation portion of the semiconductor storage device 1 can be disposed is determined by standards or specifications. In this way, in the semiconductor storage device 1, there are cases in which providing the heat dissipation portion on the side in the −Z direction of the housing 10 is restricted.

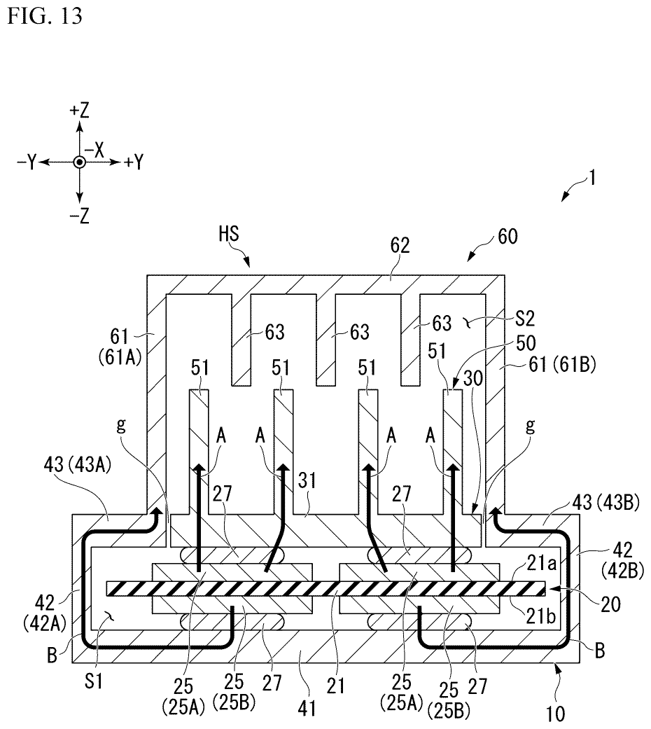

FIG. 13 is a cross-sectional view for explaining a function of the heat dissipation structure HS according to the present embodiment. Here, a minute gap g for assembling the first member 30 and the second member 40 is present between the first wall 31 of the first member 30 and the fourth walls 43A and 43B of the second member 40. Therefore, heat transfer between the first member 30 and the second member 40 is limited.

The arrow A in the drawing indicates a transfer path of heat generated by heat generating parts (for example, the controller 23, the DRAM 24A, and the NAND 25A) mounted on the first surface 21a of the board 21. At least some of the heat generated by the heat generating parts mounted on the first surface 21a of the board 21 is transferred from the heat generating parts to the plurality of fins 51 of the first heat dissipation portion 50 via the heat conductive member 27 and the first wall 31. The heat transferred to the plurality of fins 51 is dissipated to the outside by, for example, air flowing through the air flow path space S2.

On the other hand, the arrow B in the drawing indicates a transfer path of heat generated by heat generating parts (for example, the DRAM 24B and the NAND 25B) mounted on the second surface 21b of the board 21. At least some of the heat generated by the heat generating parts mounted on the second surface 21b of the board 21 is transferred from the heat generating parts to the third wall 42 and the fourth wall 43 of the second member 40 via the heat conductive member 27 and the second wall 41. In the present embodiment, the third wall 42 and the fourth wall 43 of the second member 40 overlap the first wall 31 of the first member 30 from the outside of the housing 10 and are exposed to the outside of the semiconductor storage device 1. Therefore, at least some of the heat that has been transferred to the third wall 42 and the fourth wall 43 of the second member 40 is dissipated to the outside of the semiconductor storage device 1 from the third wall 42 and the fourth wall 43.

Also, some of the heat that has been transferred to the third wall 42 and the fourth wall 43 is transferred from the third wall 42 and the fourth wall 43 to the second heat dissipation portion 60. Some of the heat transferred to the second heat dissipation portion 60 is dissipated to the outside of the semiconductor storage device 1 from the upright portion 61 and the ceiling portion 62 of the second heat dissipation portion 60. Also, some of the heat transferred to the second heat dissipation portion 60 is transferred to the plurality of fins 63. The heat transferred to the plurality of fins 63 is dissipated to the outside by, for example, the air flowing through the air flow path space S2.

### <4. Advantages>

As a comparative example, a structure in which the housing 10 is formed by a base member having the second wall 41 and a cover member having the first wall 31, the third wall 42, the fourth wall 43, and the plurality of fins 51 will be considered. In a configuration of such a comparative example, the base member and the cover member are separate entities. At least some of heat transferred to the first wall 31 from the heat generating parts mounted on the first surface 21a of the board 21 is dissipated to the outside by the first wall 31, the third wall 42, the fourth wall 43, and the plurality of fins 51. On the other hand, the heat from the heat generating parts mounted on the second surface 21b of the board 21 is transferred to the second wall 41 and dissipated. However, since a heat dissipation area is limited, it is difficult to promote heat dissipation. Therefore, the heat transferred from the board 21 to the first wall 31 and the heat transferred from the board 21 to the second wall 41 may be difficult to dissipate to the outside in a balanced manner, and improvement in heat dissipation performance of the semiconductor storage device may be difficult to achieve.

On the other hand, in the present embodiment, the semiconductor storage device 1 has the housing 10 and the heat dissipation structure HS. The heat dissipation structure HS is provided in the housing 10. The housing 10 has the first member 30 and the second member 40. The first member 30 has the first wall part (for example, the first wall 31). The first wall part includes a portion exposed to the outside of the housing 10, and faces the board 21 from the side in the +Z direction. The second member 40 has the second wall part (for example, the second wall 41). The second wall part includes a portion exposed to the outside of the housing 10, and faces the board 21 from the side in the −Z direction. The heat dissipation structure HS includes the plurality of fins 51 protruding from the first wall 31 toward a side opposite to the board 21. The second member 40 has the third wall part (for example, the third wall 42 or the fourth wall 43) that overlaps a part of the first member 30 from the outside of the housing 10 when viewed from a direction in which the plurality of fins 51 are aligned. For example, the second wall part and the third wall part are integrally formed. For example, the second member 40 is a single-piece member including the second wall part and the third wall part.

According to such a configuration, at least some of the heat transferred from the board 21 to the first wall part is dissipated to the outside by the plurality of fins 51. On the other hand, at least some of the heat transferred from the board 21 to the second wall part is dissipated to the outside by the third wall part that overlaps the first member 30 from the outside of the housing 10. Therefore, for example, compared to the configuration of the comparative example described above, the heat transferred from the board 21 to the first wall part and the heat transferred from the board 21 to the second wall part can be dissipated to the outside in a balanced manner. Therefore, improvement in heat dissipation performance of the semiconductor storage device 1 can be achieved.

In the present embodiment, the third wall part overlaps the first wall part from the outside of the housing 10 when viewed from a direction in which the plurality of fins 51 are aligned. According to such a configuration, at least some of the heat transferred from the board 21 to the second wall part is dissipated to the outside by the third wall part that overlaps the first wall part from the outside of the housing 10. Therefore, the heat transferred from the board 21 to the first wall part and the heat transferred from the board 21 to the second wall part can be dissipated in a balanced manner. Therefore, improvement in heat dissipation performance of the semiconductor storage device 1 can be achieved.

In the present embodiment, the housing 10 has the housing space S1 in which the board 21 is housed. The first wall part faces the housing space S1 from the side in the +Z direction. The second wall part faces the housing space S1 from the side in the −Z direction. The third wall part (for example, the fourth wall 43) faces the housing space S1 from the side in the +Z direction. According to such a configuration, at least some of the heat transferred from the board 21 to the second wall part is dissipated to the outside by the third wall part positioned on the side in the +Z direction with respect to the housing space S1. Therefore, further improvement in heat dissipation performance of the semiconductor storage device 1 can be achieved.

In the present embodiment, the heat dissipation structure HS includes the first heat dissipation portion 50 including the plurality of fins 51 and the second heat dissipation portion 60 provided on the second member 40. At least a part of the second heat dissipation portion 60 overlaps at least a part of the plurality of fins 51 when viewed from a direction in which the plurality of fins 51 are aligned. According to such a configuration, at least some of the heat transferred from the board 21 to the second wall part is dissipated to the outside by the second heat dissipation portion 60 that is disposed to be aligned with at least a part of the plurality of fins 51. Therefore, further improvement in heat dissipation performance of the semiconductor storage device 1 can be achieved.

In the present embodiment, the second heat dissipation portion 60 includes the plurality of second fins 63. The plurality of second fins 63 are aligned in a direction in which the plurality of fins 51 are aligned. According to such a configuration, at least some of heat transferred from the board 21 to the second wall part is dissipated to the outside by the plurality of fins 63. Therefore, further improvement in heat dissipation performance of the semiconductor storage device 1 can be achieved.

In the present embodiment, the second heat dissipation portion 60 has the upright portion 61 and the ceiling portion 62. The upright portion 61 overlaps the plurality of fins 51 when viewed from a direction in which the plurality of fins 51 are aligned. The ceiling portion 62 is supported by the upright portion 61 and is disposed on a side opposite to the first wall part with respect to the plurality of fins 51. The plurality of fins 63 protrude from the ceiling portion 62 toward the first wall part. According to such a configuration, at least some of the heat transferred from the board 21 to the second wall part is dissipated to the outside by the plurality of fins 63 disposed on a side opposite to the first wall part with respect to the plurality of fins 51. Therefore, further improvement in heat dissipation performance of the semiconductor storage device 1 can be achieved.

In the present embodiment, at least one fin 63 included in the plurality of fins 63 is disposed to correspond to a position between two fins 51 included in the plurality of fins 51. According to such a configuration, it is easier for air to flow around the plurality of fins 51 and the plurality of fins 63. Therefore, further improvement in heat dissipation performance of the semiconductor storage device 1 can be achieved.

In the present embodiment, the third wall part (for example, the third wall 42) has the engagement portion 44. The first member 30 has the engagement portion 32 whose position in the Z direction is restricted by engaging with the engagement portion 44. According to such a configuration, the number of fastening members required for assembling the semiconductor storage device 1 can be reduced by utilizing the engagement portion 44 provided on the third wall part which contributes to improvement in heat dissipation performance. Therefore, it is possible to achieve either or both the effects of improvement in assembly and reduction in manufacturing costs in the semiconductor storage device 1.

### Second Embodiment

Next, a second embodiment will be described. The second embodiment differs from the first embodiment in that the second heat dissipation portion 60 does not have the fin 63 or the like. Note that, configurations other than those described below are the same as the configurations of the first embodiment.

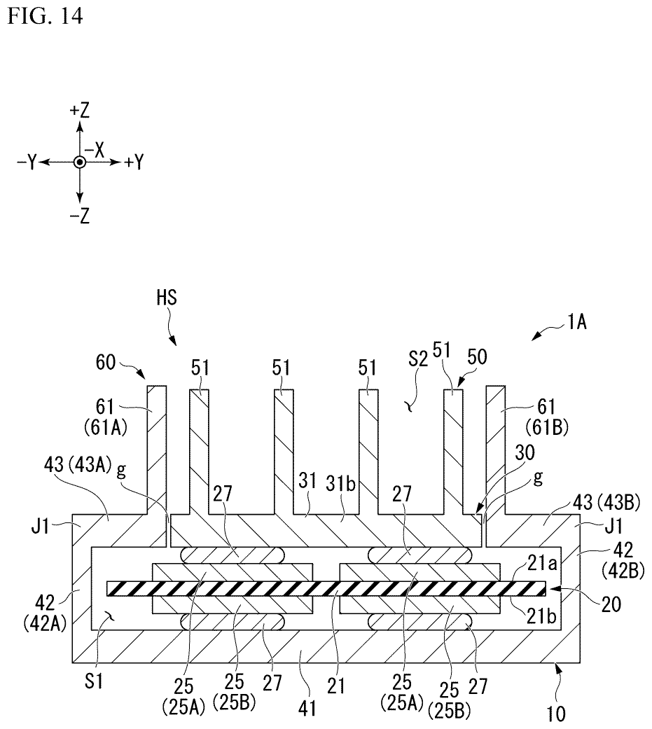

FIG. 14 is a cross-sectional view showing a semiconductor storage device 1A according to the second embodiment. In the present embodiment, the second heat dissipation portion 60 does not have the ceiling portion 62 and the fin 63. An air flow path space S2 is open in the +Z direction. An upright portion 61 of the second heat dissipation portion 60 functions as, for example, a fin.

According to such a configuration, at least some of heat transferred from a board 21 to a first wall 31 is dissipated to the outside by a plurality of fins 51. On the other hand, at least some of heat transferred from the board 21 to a second wall 41 is dissipated to the outside by the third wall part (a third wall 42 or a fourth wall 43) that overlaps a first member 30 from the outside of a housing 10 and the upright portion 61 of the second heat dissipation portion 60. Therefore, for example, compared to the configuration of the comparative example described above, the heat transferred from the board 21 to the first wall 31 and the heat transferred from the board 21 to the second wall 41 can be dissipated to the outside in a balanced manner. Therefore, improvement in heat dissipation performance of the semiconductor storage device 1A can be achieved.

### Third Embodiment

Next, a third embodiment will be described. The third embodiment differs from the first embodiment in that the second heat dissipation portion 60 is not provided. Note that, configurations other than those described below are the same as the configurations of the first embodiment.

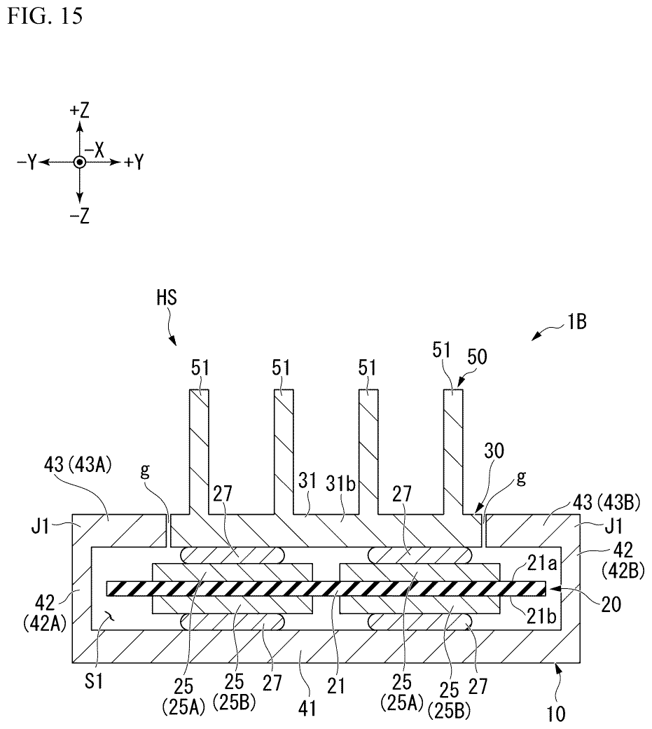

FIG. 15 is a cross-sectional view showing a semiconductor storage device 1B according to the third embodiment. In the present embodiment, the second heat dissipation portion 60 is not provided.

According to such a configuration, at least some of heat transferred from a board 21 to a first wall 31 is dissipated to the outside by a plurality of fins 51. On the other hand, at least some of heat transferred from the board 21 to a second wall 41 is dissipated to the outside by the above-described third wall part (a third wall 42 or a fourth wall 43) that overlaps a first member 30 from the outside of a housing 10. Therefore, for example, compared to the configuration of the comparative example described above, the heat transferred from the board 21 to the first wall 31 and the heat transferred from the board 21 to the second wall 41 can be dissipated to the outside in a balanced manner. Therefore, improvement in heat dissipation performance of the semiconductor storage device 1B can be achieved.

### Fourth Embodiment

Next, a fourth embodiment will be described. The fourth embodiment differs from the first embodiment in that a first heat dissipation portion 50 has a plurality of protruding portions 51A, and a second heat dissipation portion 60 has a plurality of protruding portions 63A. Note that, configurations other than those described below are the same as the configurations of the first embodiment.

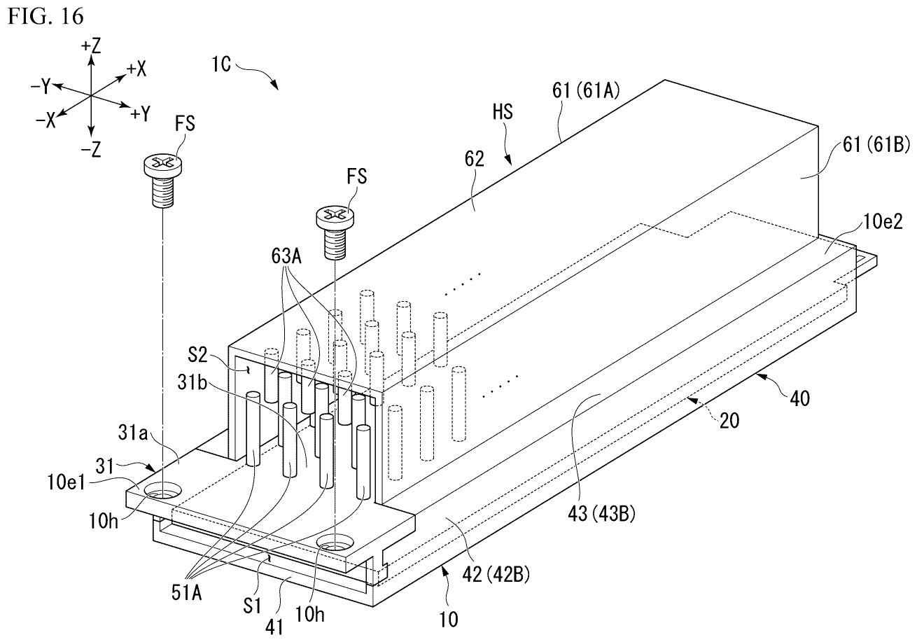

FIG. 16 is a cross-sectional view showing a semiconductor storage device 1C according to the fourth embodiment. In the present embodiment, the first heat dissipation portion 50 has the plurality of protruding portions 51A instead of the plurality of fins 51. The plurality of protruding portions 51A protrude in the +Z direction from a first wall 31. The protruding portions 51A each have, for example, a columnar shape, but may also have a prismatic shape, a conical shape, or a pyramidal shape. The plurality of protruding portions 51A are disposed at intervals in the X and Y directions. Similarly, the second heat dissipation portion 60 has the plurality of protruding portions 63A instead of the plurality of fins 63. The plurality of protruding portions 63A protrude in the −Z direction from a ceiling portion 62. The protruding portions 63A each have, for example, a columnar shape, but may also have a prismatic shape, a conical shape, or a pyramidal shape. The plurality of protruding portions 63A are disposed at intervals in the X and Y directions.

According such a configuration, at least some of heat transferred from a board 21 to the first wall 31 is dissipated to the outside by the plurality of protruding portions 51A. On the other hand, at least some of heat transferred from the board 21 to the second wall 41 is dissipated to the outside by the above-described third wall part (a third wall 42 or a fourth wall 43) that overlaps a first member 30 from the outside of a housing 10, the plurality of protruding portions 63A, and the like. Therefore, for example, compared to the configuration of the comparative example described above, the heat transferred from the board 21 to the first wall 31 and the heat transferred from the board 21 to the second wall 41 can be dissipated to the outside in a balanced manner. Therefore, improvement in heat dissipation performance of the semiconductor storage device 1C can be achieved.

While preferred embodiments have been described, the embodiments are not limited to the above-described examples. For example, the plurality of embodiments may be realized in combination with each other.

According to at least one of the embodiments described above, the semiconductor storage device according to the embodiment includes a housing, a board, a semiconductor memory, and a heat dissipation structure. The housing has a first member and a second member. When a thickness direction of the board is defined as a first direction, the first member has a first wall part facing the board from a first side in the first direction. The second member has a second wall part facing the board from a second side, which is on a side opposite to the first side, in the first direction. The heat dissipation structure includes a plurality of first fins protruding from the first wall part toward a side opposite to the board. The second member further includes a third wall part that overlaps a part of the first member from the outside of the housing when viewed from a second direction in which the plurality of first fins are aligned. According to such a configuration, improvement in heat dissipation performance of the semiconductor storage device can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a housing;
a board in the housing;
a semiconductor memory on the board; and
a heat dissipation structure in the housing, wherein
the housing includes a first member and a second member,
when a thickness direction of the board is defined as a first direction,
the first member includes a first wall part, the first wall part includes a portion exposed to the outside of the housing, the first wall part faces the board from a first side in the first direction,
the second member includes a second wall part, the second wall part includes a portion exposed to the outside of the housing, the second wall part faces the board from a second side in the first direction, the second side is on a side opposite to the first side, wherein
the heat dissipation structure includes a plurality of first fins,
the plurality of first fins protrude from the first wall part toward a side opposite to the board,
the second member further includes a third wall part,
the third wall part overlaps a part of the first member from the outside of the housing when viewed from a second direction, and
the second direction is a direction in which the plurality of first fins are arranged.

2. The semiconductor storage device according to claim 1, wherein
the third wall part overlaps the first wall part from the outside of the housing when viewed from the second direction.

3. The semiconductor storage device according to claim 2, wherein
the second member is a single-piece member including the second wall part and the third wall part.

4. The semiconductor storage device according to claim 2, wherein
the housing has a housing space,
the board is in the housing space,
the first wall part faces the housing space from the first side in the first direction,
the second wall part faces the housing space from the second side in the first direction, and
the third wall part faces the housing space from the first side in the first direction.

5. The semiconductor storage device according to claim 2, wherein
the heat dissipation structure includes a first heat dissipation portion and a second heat dissipation portion,
the first heat dissipation portion includes the plurality of first fins,
the second heat dissipation portion is on the second member, and
at least a part of the second heat dissipation portion overlaps at least a part of the plurality of first fins when viewed from the second direction.

6. The semiconductor storage device according to claim 2, wherein
the third wall part includes a first engagement portion,
the first member includes a second engagement portion, and
a position of the second engagement portion in the first direction is restricted by engagement between the first engagement portion and the second engagement portion.

7. The semiconductor storage device according to claim 2, further comprising
a controller on the board, wherein
at least one first fin included in the plurality of first fins overlaps the semiconductor memory and the controller when viewed from the first direction.

8. The semiconductor storage device according to claim 1, wherein
the second member is a single-piece member including the second wall part and the third wall part.

9. The semiconductor storage device according to claim 1, wherein
the housing has a housing space,
the board is in the housing space,
the first wall part faces the housing space from the first side in the first direction,
the second wall part faces the housing space from the second side in the first direction, and
the third wall part faces the housing space from the first side in the first direction.

10. The semiconductor storage device according to claim 1, wherein
the heat dissipation structure includes a first heat dissipation portion and a second heat dissipation portion,
the first heat dissipation portion includes the plurality of first fins,
the second heat dissipation portion is on the second member, and
at least a part of the second heat dissipation portion overlaps at least a part of the plurality of first fins when viewed from the second direction.

11. The semiconductor storage device according to claim 10, wherein
the second heat dissipation portion includes a plurality of second fins in the second direction.

12. The semiconductor storage device according to claim 11, wherein
the second heat dissipation portion further includes an upright portion and a ceiling portion,
the upright portion overlaps the plurality of first fins when viewed from the second direction,
the ceiling portion is supported by the upright portion,
the ceiling portion is on a side opposite to the first wall part with respect to the plurality of first fins, and
the plurality of second fins protrude from the ceiling portion toward the first wall part.

13. The semiconductor storage device according to claim 12, wherein
at least one second fin of the plurality of second fins correspond to a position between two first fins of the plurality of first fins.

14. The semiconductor storage device according to claim 1, wherein
the third wall part includes a first engagement portion,
the first member includes a second engagement portion, and
a position of the second engagement portion in the first direction is restricted by engagement between the first engagement portion and the second engagement portion.

15. The semiconductor storage device according to claim 1, further comprising
a controller on the board, wherein
at least one first fin included in the plurality of first fins overlaps the semiconductor memory and the controller when viewed from the first direction.

16. The semiconductor storage device according to claim 1, wherein
the first wall part is away from the third wall part by a gap.

17. A semiconductor storage device comprising:
a housing;
a board in the housing;
a semiconductor memory on the board; and
a heat dissipation structure in the housing, wherein
the housing includes a first member and a second member,
when a thickness direction of the board is defined as a first direction,
the first member includes a first wall part, the first wall part includes a portion exposed to the outside of the housing, the first wall part faces the board from a first side in the first direction,
the second member includes a second wall part, the second wall part includes a portion exposed to the outside of the housing, the second wall part faces the board from a second side in the first direction, the second side is on a side opposite to the first side, wherein
the heat dissipation structure includes a first heat dissipation portion and a second heat dissipation portion,
the first heat dissipation portion is on the first member,
the second heat dissipation portion is on the second member,
the first heat dissipation portion includes a plurality of first fins on the first wall part, and
the second heat dissipation portion includes a plurality of second fins on a side opposite to the second wall part with respect to the first wall part.

18. The semiconductor storage device according to claim 17, wherein
the housing has a housing space,
the board is in the housing space,
the first wall part faces the housing space from the first side in the first direction, and
the second wall part faces the housing space from the second side in the first direction.

19. A semiconductor storage device comprising:
a housing;
a board in the housing;
a semiconductor memory on the board; and
a heat dissipation structure in the housing, wherein
the housing includes a first member and a second member,
when a thickness direction of the board is defined as a first direction,
the first member includes a first wall part, the first wall part includes a portion exposed to the outside of the housing, the first wall part faces the board from a first side in the first direction,
the second member includes a second wall part, the second wall part includes a portion exposed to the outside of the housing, the second wall part faces the board from a second side in the first direction, the second side is on a side opposite to the first side, wherein
the heat dissipation structure includes a plurality of protruding portions,
the plurality of protruding portions protrude from the first wall part toward a side opposite to the board,
the second member further includes a third wall part,
the third wall part overlaps a part of the first member from the outside of the housing when viewed from a second direction, and
the plurality of protruding portions are in the second direction.

20. The semiconductor storage device according to claim 19, wherein
the housing has a housing space,
the board is in the housing space,
the first wall part faces the housing space from the first side in the first direction, and
the second wall part faces the housing space from the second side in the first direction.
